(19) United States
(12) Patent Application Publication
(10) Pub. No.: US 2026/0190309 A1
(43) Pub. Date: Jul. 2, 2026

(54) ELECTRICALLY CONDUCTIVE GASKET AND ELECTROMAGNETIC WAVE SHIELDING DEVICE APPLYING SAME

(71) Applicant: JOINSET CO., LTD., Ansan-si (KR)

(72) Inventors: Sun-Ki Kim, Gunpo-si (KR); Jin-San Kim, Ansan-si (KR); Byung-Joo Park, Ansan-si (KR)

(21) Appl. No.: 19/543,834

(22) Filed: Feb. 18, 2026

Related U.S. Application Data
(63) Continuation of application No. PCT/KR2024/015886, filed on Oct. 18, 2024.

(30) Foreign Application Priority Data
Oct. 20, 2023 (KR) 10-2023-0141545
Jul. 10, 2024 (KR) 10-2024-0091313
Jul. 29, 2024 (KR) 10-2024-0100113

(51) Int. Cl. H05K 9/00; H05K 7/20

(52) U.S. Cl. CPC H05K 9/0015; H05K 7/20; H05K 9/0024; H05K 9/0045; H05K 9/0047

(57) ABSTRACT

Disclosed are an electrically conductive gasket and an electromagnetic wave shielding device applying same, the gasket being easily pressed with a small force due to the restoring force of a bending portion of a polymer film and achieving reliable electrical contact with an object. The electrically conductive gasket comprises a polymer film having an adhesive layer formed on the inner surface thereof and a metal layer formed on the outer surface thereof, wherein the polymer film is bent to surround the adhesive layer on at least one side so as to form a bending portion, the adhesive layer is not adhered to itself at least a part of the bending portion such that an inner space surrounded by the polymer film is formed, the adhesive layer is adhered to itself at a part, excluding the bending portion, where the polymer film overlaps such that a support layer is formed, and a support part is formed by the support layer and the part where the polymer film overlaps.

### REFERENCE TO RELATED APPLICATIONS

This is a continuation of International Patent Application PCT/KR2024/015886 filed on Oct. 18, 2024, which designates the United States and claims priority of Korean Patent Application No. 10-2023-0141545 filed on Oct. 20, 2023, Korean Patent Application No. 10-2024-0091313 filed on Jul. 10, 2024, and Korean Patent Application No. 10-2024-0100113 filed on Jul. 29, 2024, the entire contents of which are incorporated herein by reference.

### FIELD OF THE INVENTION

The present invention relates to an electrically conductive gasket, and more particularly, to an electrically conductive gasket, which has a low height, is capable of being pressed downward largely by small force, and achieves reliable electrical contact with an object. In addition, the present invention relates to a technology that efficiently shields emission and introduction of electromagnetic waves with respect to a semiconductor chip, and optionally, effectively releases heat generated in the semiconductor chip to the outside.

### BACKGROUND OF THE INVENTION

In general, an electrically conductive gasket interposed between electrically conductive objects, which face each other, to electrically connect the objects has to have good electrical conductivity and excellent elastic restoring property.

Such an electrically conductive gasket is mounted on an object to shield electromagnetic waves generated from electronic components such as semiconductor chips or electrically connects objects to each other.

Korean Patent Registration No. 1804881, which is proposed by the present inventor, discloses an electrical contact terminal, i.e., a coreless elastic electrical contact terminal, which is interposed between objects and in contact with the objects to provide an electrical path between the objects. The coreless elastic electrical contact terminal includes: a polymer film having an outer surface to which a metal layer adheres; and a support layer made of an elastic material, which adheres to an inner surface of the film by curing. Here, both sidewalls of the film are bent at a certain curvature radius, wherein a) a portion of a space inside both the bent sidewalls is filled with the support layer, and the objects are supported by elastic force of the filled support layer, or b) the support layer is applied inside both the bent sidewalls to constitute an elastic sheet together with the film so as to support the objects by restoring force of the elastic sheet.

However, since such the electrical contact terminal has a top surface that is entirely flat, there is a disadvantage in that it is difficult to press the flat objects with small force.

That is, there is a limitation in providing a structure of the electric contact terminal having a large pressing operation distance by being largely pressed in a height direction with less pressing force, and it is difficult to reliably limit the pressed height of the electric contact terminal.

In addition, since a bottom surface of the electrical contact terminal is entirely flat, it is difficult to allow the metal layer of the electrical contact terminal to be in direct electrical contact with the electrically conductive object due to a thickness of an adhesive tape when the adhesive tape adheres to the bottom surface of the electrical contact terminal.

In addition, when applied to a semiconductor chip mounted on a circuit board, there is a limitation in that it is difficult to shield a large amount of electromagnetic waves introduced and emitted in a direction, in which the polymer film of the electrical contact terminal is not covered with respect to the sidewalls of the semiconductor chip.

A metal shield can having an opening to protect the semiconductor chip while shielding the electromagnetic waves of the semiconductor chip mounted on the circuit board and to transfer and disperse heat generated in the semiconductor chip is applied.

For example, Korean Patent Registration No. 2413323 discloses a structure in which a conductive gasket is interposed between a frame and a shield can to physically and electrically couple the shield can to the frame so as to maintain contact between the shield can and the frame.

However, according to the related art, there is a limitation in efficiently shielding electromagnetic waves while effectively transferring heat through the semiconductor chip and the frame.

In other words, there is a limitation in that the conductive gasket is pressed against the facing object with low force and has an overall thin thickness, pressing force applied when the frame presses the semiconductor chip in a vertical direction is not applied to be concentrated only on the top surface of the semiconductor chip but is dispersed, and the conductive gasket and the shield can are integrated to be picked up and mounted at once.

### SUMMARY OF THE INVENTION

Therefore, an object of the present invention is to provide an electrically conductive gasket having small thickness that is capable of being pressed with less force.

Another object of the present invention is to provide an electrically conductive gasket having a small thickness at which direct electrical contact or reliable electrical contact with an electrically conductive object is facilitated.

Further another object of the present invention is to provide an electrically conductive gasket having a small thickness at which an opening capable of accommodating a semiconductor chip therein is easily formed, and a large amount of electromagnetic waves introduced or emitted in a horizontal direction of the semiconductor chip accommodated in the opening is shielded.

Further another object of the present invention is to provide an electromagnetic wave shielding device that is largely pressed with small force between objects and allows the objects to be in elastic contact with each other with low electrical resistance.

Further another object of the present invention is to provide an electromagnetic wave shielding device having a structure that facilitates limitation of force applied to a top surface of a semiconductor chip.

Further another object of the present invention is to provide an electromagnetic wave shielding device having a structure that efficiently transfers heat generated in a semiconductor chip to a cooling unit while efficiently shielding electromagnetic waves generated at a side surface of the semiconductor chip or electromagnetic waves introduced into the semiconductor chip.

According to the above objects, an electrically conductive gasket, which is interposed between facing objects to shield electromagnetic waves or provide electrical connection the facing objects, includes: an electrically conductive member; and an electrically conductive film provided as a curable adhesive layer having elasticity, which adheres to the electrically conductive member by curing, wherein the electrically conductive film is bent in a curved shape at each of both sides of the electrically conductive gasket in a width direction so that the adhesive layer is disposed inside to provide a bending portion having one inner space extending in a longitudinal direction of the electrically conductive gasket, the adhesive layers adhere to each other at a portion at which the electrically conductive films overlap to face each other except for the bending portion to provide a support layer, wherein a support part is provided by the portion, at which the electrically conductive films overlap each other, and the support layer, a maximum height of the bending portion is higher than a maximum height of the support part, and when each of the objects presses the gasket, the gasket is in contact with elastic contact with the object due to elastic restoring force of the bending portion.

Preferably, the electrically conductive member may be a polymer film having one surface, on which a metal layer is disposed, and the other surface, to which the adhesive layer adheres, or an electrically conductive fiber to which the adhesive layer adheres, and the metal layer may be provided by plating or provided as metal foil.

Preferably, the support part may be flat, and both ends of the electrically conductive member may be disposed on a bottom surface of the support part.

Preferably, a plurality of microvoids caused by air, which is smaller than the inner space, may be provided in the support layer to more soften the support part.

Preferably, a cross-section of the electrically conductive gasket may be symmetrical in the width direction, and a cross-section of the bending portion may have a circular or elliptical shape in which a height of an intermediate portion in a horizontal direction becomes a maximum height.

Preferably, an adhesive tape may adhere to the electrically conductive member disposed on a bottom surface of the support part, wherein the tape may not protrude beyond the lowermost portion of the bending portion so that the electrically conductive member disposed on the bottom surface of the support part is in direct contact with the object.

Preferably, one or more openings passing through the electrically conductive gasket in a thickness direction may be defined in a portion of the support part, and a maximum height of the gasket at the bending portion may be greater than a maximum height of a semiconductor chip accommodated in each of the openings and mounted on a circuit board.

Preferably, electrically conductive powder may be mixed into the support layer to shield electromagnetic waves, which are introduced into or emitted from the semiconductor chip accommodated in the opening in a direction, in which the bending portion is not provided through the support layer.

Preferably, the electrically conductive member may include: a polymer film having one surface on which a metal layer is disposed, or an electrically conductive fiber adheres; and a flat reinforcing sheet having one surface, to which the other surface of the polymer film adheres, and the other surface, to which the adhesive layer adheres.

Preferably, an inner space surrounded by the electrically conductive film may be defined in the bending portion because the adhesive layers do not adhere to each other, or the adhesive layers may adhere to each other on the bending portion so as to be connected to the support layer.

According to the above objects, an electromagnetic wave shielding device, which surrounds a semiconductor chip mounted on a circuit board to shield electromagnetic waves, includes: a metal shield case having an opening in a top surface thereof and provided with a flange along an edge of the opening; and an electrically conductive gasket attached to a top surface of the flange, wherein the electrically conductive gasket comprises the electrically conductive member, and an electrically conductive film provided as a curable adhesive layer having elasticity, which adheres to the electrically conductive member by curing, the electrically conductive film is bent in a curved shape at each of both sides of the electrically conductive gasket in a width direction so that the adhesive layer is disposed inside to provide a bending portion having one inner space extending in a longitudinal direction of the electrically conductive gasket, the adhesive layers adhere to each other at a portion at which the electrically conductive films overlap to face each other except for the bending portion to provide a support layer, wherein a support part is provided by the portion, at which the electrically conductive films overlap each other, and the support layer, an opening passing through the electrically conductive gasket in a thickness direction is defined in the support part, a maximum height of the bending portion is higher than a maximum height of the support part, when each of the objects presses the gasket, the gasket is in contact with elastic contact with the object due to elastic restoring force of the bending portion, and a surface of the semiconductor chip is exposed to the outside through the opening of the gasket and the opening of the shield case.

Preferably, the opening of the metal shield gasket and the opening of the electrically conductive gasket may correspond to each other so that surfaces of two or more semiconductor chips are exposed to the outside.

Preferably, the electrically conductive gasket may be mounted inside an edge of the metal shield case, the electrically conductive gasket may correspond to a soldering temperature, the metal shield case may be suitable for soldering, and the electromagnetic wave shielding device may be surface-mounted by vacuum pickup at a portion of the electrically conductive gasket.

According to the present invention, since the bending portion has the height higher than that of the support part, it may be pressed with less force.

In addition, the reliable electrical contact with the object may be achieved due to the elastic restoring force of the bending portion and the thickness of the adhesive tape.

In addition, the electrically conductive gasket may not be pressed below the certain height due to the electrically conductive powder of the support layer, and the large amount of electromagnetic waves that are introduced and emitted into/from the side surface of the semiconductor chip accommodated in the opening of the electrically conductive gasket may be shielded.

In addition, the force exerted by the object such as the cooling unit may be commonly shared by the electrically conductive gasket, which has a thin thickness and elasticity that is capable of being largely pressed with the less force, the metal shield case, and the semiconductor chip or may not be applied to the at least semiconductor chip alone to prevent the semiconductor chip from being damaged and quickly transfer the heat generated in the semiconductor chip to the cooling unit while effectively shielding the electromagnetic waves of the semiconductor chip.

In addition, when the support layer is electrically conductive, the electromagnetic waves of the electrically conductive gasket including both the ends, which are not covered by the polymer film, in the horizontal direction may be shielded.

In addition, the gas caused by the difference in height between the shield can and the semiconductor chip may be filled with the electrically conductive gasket, which has the thin thickness and is largely pressed with the small force, and the thermoelectric member having the low hardness to quickly transfer the heat generated in the semiconductor chip while effectively shielding the electromagnetic waves.

### BRIEF DESCRIPTION OF THE DRAWINGS

FIG. 1 is a view illustrating an electrically conductive gasket according to an embodiment of the present invention.

FIG. 2 is a cross-sectional view taken along line 2-2′ of FIG. 1.

FIG. 3 is a view illustrating an electrically conductive gasket according to another embodiment of the present invention.

FIG. 4 is a view illustrating a state in which the electrically conductive gasket is mounted on a circuit board.

FIG. 5 is an exploded view illustrating an electromagnetic wave shielding device according to an embodiment of the present invention.

FIG. 6 is a cross-sectional view illustrating an integrated electromagnetic wave shielding device.

FIG. 7 is a view illustrating a state in which the electromagnetic wave shielding device is applied.

FIG. 8 is a view illustrating an electrically conductive gasket according to another embodiment of the present invention.

### DETAILED DESCRIPTION OF THE INVENTION

It should be noted that technical terms used in the present invention are only used to describe particular embodiments and are not intended to limit the present invention. In addition, the technical terms used in the present invention should be interpreted as having a meaning generally understood by a person of ordinary skill in the technical field to which the present invention belongs, unless specifically defined to have a different meaning in the present invention, and should not be interpreted in an overly comprehensive meaning or an overly narrow meaning.

Hereinafter, the present invention will be described in more detail with reference to the accompanying drawings. Herein, the accompanying drawings are for the purpose of assisting the understanding of the present invention, and some components may be disregarded or shown somewhat exaggeratedly in dimension and the like for convenience of description.

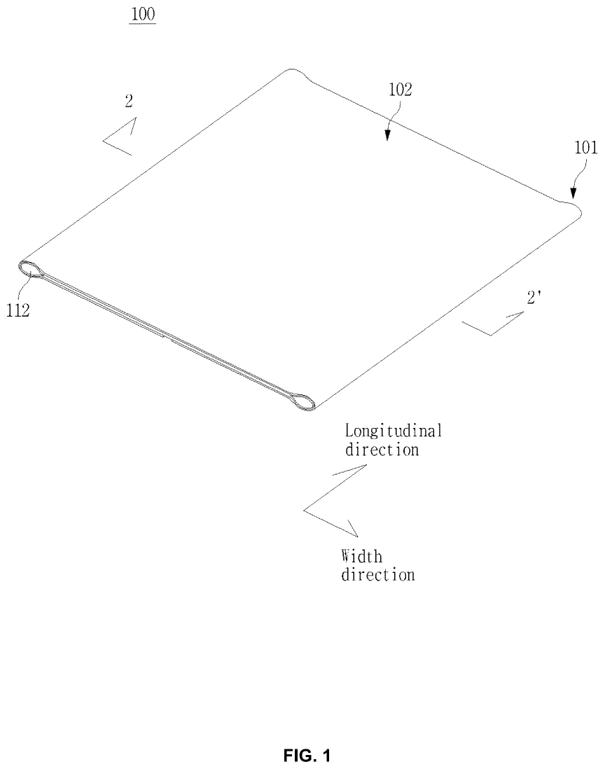

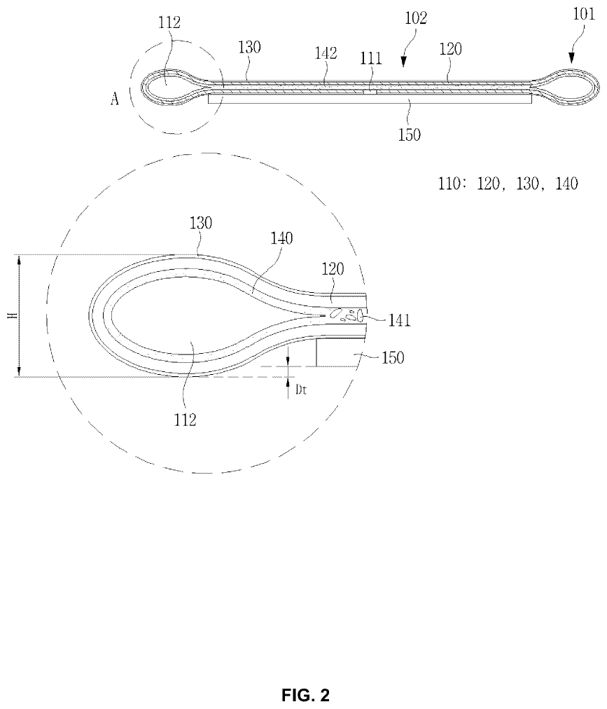

FIG. 1 is a view illustrating an electrically conductive gasket according to an embodiment of the present invention, and FIG. 2 is a cross-sectional view taken along line 2-2′ of FIG. 1.

An electrically conductive gasket 100 has a small thickness and elastic restoring force and is interposed to be pressed between electrically conductive objects, which face each other, to shield electromagnetic waves or electrically connect the objects to each other.

The electrically conductive gasket 100 preferably corresponds to a soldering temperature to allow for reflow soldering by solder cream.

As illustrated in FIG. 1, the electrically conductive gasket 100 has a sheet shape of which a width and length are significantly larger than a thickness. A bending portion 101 having an elliptical cross-section is disposed at both sides of an electrically conductive film 110 in a width direction, and a flat support part 102 is disposed between the bending portions 101.

In this embodiment, the bending portions 101 may be respectively provided at both the sides of the electrically conductive film 110 in the width direction, but the bending portion 101 may be provided on at least one side of the electrically conductive film 110.

A height of the thickest portion of the electrically conductive gasket 100, i.e., a maximum height H of the bending portion 101, ranges of 0.15 mm to 1.2 mm, and preferably ranges of 0.15 mm to 0.5 mm, but is not limited thereto.

The electrically conductive film 110 is constituted by a polymer film 120 having an outer surface, on which a metal layer 130 is disposed, and an adhesive layer 140 disposed on an inner surface of the polymer film 120.

In this embodiment, the polymer film 120 provided with the metal layer 130 on the outer surface thereof is an example of an electrically conductive member. Alternatively, other structures may be provided as well.

For example, the electrically conductive member may be a metal deposition layer or metal plating layer formed on the polymer film 120 by metal deposition or metal plating, metal foil formed on the polymer film 120, or an electrically conductive fiber (such as a woven fabric or non-woven fabric) plated with a metal. The electrically conductive fiber may adhere to the polymer film 120 or may be used without the polymer film 120.

Thus, the electrically conductive film 110 may be constituted by an electrically conductive member and an adhesive layer 140 formed to adhere thereto, and a reinforcing sheet may be further interposed between the electrically conductive member and the adhesive layer 140.

The reinforcing sheet may adhere to the electrically conductive member. For example, the reinforcing sheet may be a rubber sheet having a certain thickness with elasticity or may be a material such as the polymer film 120.

The electrically conductive film 110 is bent so that the adhesive layer 140 is disposed at an inner side at both sides facing each other in the width direction to provide the bending portion 101 provided with a single inner space 112 extending in a length direction of the gasket.

In addition, the adhesive layers 140 may adhere to each other at portions at which the electrically conductive films 110 overlap each other except for the bending portion 101 to provide the support layer 142, thereby constituting a support part 102 together with the electrically conductive film 110.

Selectively, to prevent the adhesive layers 140 from adhering to each other at the bending portion 101, the adhesive layer 140 may not be provided at the bending portion 101 at all.

The metal layer 130 may be made of a material that is suitable for reflow soldering using solder cream. However, it is most preferable to use a metal layer formed by plating on the polymer film 120 as the metal layer 130.

The adhesive layer 140 is, for example, elastic rubber formed by curing liquid silicone rubber or polyurethane rubber. Here, the cured silicone rubber corresponds to the soldering temperature.

The polymer film 120 may be a conventional polyimide (PI) film or polyester (PET) film having certain or more mechanical strength. It is preferable that the polymer film 120 has a thickness greater than that of the metal layer 130 so that elastic restoration is well achieved, and damage due to external force is reduced when the bending portion 101 in which the inner space 112 is defined is pressed, and when the polymer film 120 is made of polyimide, the thickness corresponds to the soldering temperature.

For example, the thickness of the polymer film 120 may be about 7 μm to about 30 μm, and the thickness of the metal layer 130 may be about 2 μm to about 15 μm. When the polymer film 120 is made of polyimide, the thickness corresponds to the soldering temperature.

The elastic restoring force at the bending portion 101 may be determined by at least one of the thicknesses of the polymer film 120 and the metal layer 130, a curvature radius of the bending portion 101, or a material, hardness, and thickness of the adhesive layer 140, and a size of the bending portion 101 corresponds appropriately to a size of the metal shield case 180.

A double-sided adhesive tape (PSA) 150 may adhere to the metal layer 130 on a bottom surface of the electrically conductive gasket 100, and thus, the electrically conductive gasket 100 may adhere to the object by the double-sided adhesive tape 150. The double-sided adhesive tape may be electrically conductive or have electrical insulation.

Referring to FIG. 2, the adhesive tape 150 may adhere to the metal layer 130 on a bottom surface of the electrically conductive gasket 100 to correspond to the support part 102 and may extend up to before the thickest portion of the bending part 101 and then adhere thereto.

The adhesive tape 150 may have a thickness so that at least a portion of the metal layer 130 on the bottom surface of the bending portion 101 is in direct electrical contact with the object when the electrically conductive gasket 100 adheres to the object by the adhesive tape 150.

In other words, as indicated by dotted lines within a circle of FIG. 2, since a level of the bottom surface of the bending portion 101 is lower than a level of the bottom surface of the adhesive tape 150, i.e., due to a level difference Dt, the bottom surface of the bending portion 101 may be in direct electrical contact with the object without being pressed against the adhesive tape 150. As a result, low electrical contact resistance is achieved.

In FIG. 2, the support layer 142 is provided by self-adhesion of the adhesive layers 140 applied to the inner surface of the polymer film 120 during the manufacturing process and is connected to the adhesive layer 140 disposed on the inner surface of the polymer film 120 at the bending portion 101.

As described above, an inner space 112 in which the adhesive layers 140 do not adhere to each other and are surrounded by the adhesive layer 140 may be defined in the bending portion 101, and the bending portion 101 may have an elliptical cross-sectional shape with a width greater than the height as in this embodiment.

The inner space 112 may be determined by an amount of adhesive corresponding to the adhesive layer 140, the thickness of the support layer 142, the dimensions of the electrically conductive gasket 100, and the manufacturing process thereof. Preferably, when pressing the bending portion 101 in which the inner space 112 is defined to the same height as the support part 102, the bending portion 101 may be pressed with less force. In other words, the force required to press the bending portion 101 in the height direction per unit area is less than the force required to press the support part 102.

According to this embodiment, since the height of the gasket at the bending portion 101, in which the inner space 112 is defined, is higher than the height of the gasket at the support part 102, when the electrically conductive gasket 100 is pressed by the object, the bending portion 101 may be pressed first against the object. As a result, a pressed distance of the electrically conductive gasket 100 may increase, and thus, the gasket may be pressed with less force.

Although varying depending on the use of the electrically conductive gasket 100, in the present invention, since the height of the electrically conductive gasket 100 is low, it is preferable that a maximum height of the gasket at the being portion 101 is 1.1 times to 2 times a maximum height of the gasket at the support part 102.

There is a disadvantage in that when the ratio is less than 1.1 times, the effect of the present invention is reduced, and when the ratio is greater than 2 times, it is difficult to form the bending portion 101 with respect to the maximum height of the gasket and to handle the bending portion 101.

According to this structure, when the electrically conductive gasket 100 is pressed by the object at a certain height in the vertical direction, the height of the gasket at the bending portion 101 is higher than the height of the gasket at the support part 102, causing the gasket to be contacted starting from the bending portion 101. Therefore, the electrically conductive gasket 100 may be pressed with less force as a whole.

Here, when the electrically conductive gasket 100 is pressed in the vertical direction by the object, since only the bending portion 101 is pressed to be directly electrically connected to the object, electrical contact with the object may be achieved with less force. However, when pressing the object together with the support part 102, lower electrical contact resistance may be achieved, and electromagnetic wave shielding performance may also be improved.

The inner space 112 of the bending portion 101 may be defined so that the adhesive layers 140 do not adhere to each other, but are separated from each other at the bending portion 101 during the process in which the electrically conductive film 110 is bent into a curve to provide the bending portion 101 and the support part 102. For example, the inner space 112 may be determined by a structure and manufacturing method of a mold used to manufacture the electrically conductive gasket 100 or an amount and viscosity of liquid adhesive, and the materials and thicknesses of the polymer film 120 and the metal layer 130.

The inner space 112 defined during the process of forming the bending portion 101 may be maintained in its shape after the liquid adhesive is cured.

Preferably, the thickness of the support layer 142 may be greater than the sum of the thickness of the polymer film 120 and the thickness of the metal layer 130 to provide appropriate elasticity.

According to this structure, the electrically conductive gasket 100 may be easily and largely pressed with the small force due to the restoring force of the bending portion 101 that defines the inner space 112 and the height of the bending portion 101, which is higher than that of the support part 102. As a result, the reliable electrical contact with the object may be achieved.

As described above, the support layer 142 provided between the polymer films 120 on the support part 102 may be provided by the self-adhesion of the adhesive layers 140 while facing each other. Since the adhesive layers 140 adhere to each other, a microvoid 141 may be defined during the process of forming the support layer 142.

The microvoid 141 may be defined by supplying air to the support layer 142 due to the restoring force of the polymer film 120 and the metal layer 130 at the support part 102, the structure and manufacturing method of the mold used for manufacturing the electrically conductive gasket, and the amount and viscosity of the liquid adhesive.

Preferably, a plurality of microvoids 141 may be defined in the support layer 142 as a whole, and the support part 102 may be softer due to the microvoid 141 having a dimension smaller than the size of the inner space 112 of the bending portion 101.

A large amount of powder having a diameter smaller than the thickness of the support layer 142, may be dispersed in the support layer 142 constituting the support part 102. The powder serves as spacers that restrict the pressed height of the support part 102 or serves to increase in mechanical strength of the support part 102.

The powder may be uniformly distributed in the adhesive layer 140, and as a result, the powder may also be uniformly dispersed in the support layer 142 provided by the self-adhesion of the adhesive layers 140.

At least one of a metal, ceramic, carbon, or a polymer may be applied as the powder.

Here, in the case of the metal powder, copper or aluminum powder may be used for shielding the electromagnetic waves, and magnetic metal powder may be used for absorbing the electromagnetic waves.

Preferably, when considering manufacturing productivity of the electrically conductive gasket 100 or the force applied to press the electrically conductive gasket 100, a maximum diameter of the powder may range of ⅕ to ⅓ of the thickness of the support layer 142, but is not limited thereto.

The support layer 142 containing the powder is manufactured by mixing the powder with liquid polymer rubber and then curing the mixture, and the lower the electric resistance of the support layer 142, the more the electrically conductive gasket 100 is pressed.

The electrically conductive metal member may be embedded in the support part 102. For example, the electrically conductive metal member may be placed between the adhesive layers 140 at a portion corresponding to the support part 102 and then self-adhere to each other to provide the support layer 142.

In addition, the electrically conductive metal member may be attached to the metal layer 130 on the bottom surface of the electrically conductive gasket 100 corresponding to the support part 102.

The metal member is, for example, in the form of foil having a uniform thickness and a width much larger than the thickness, made of copper, iron, or an alloy thereof. The electrically conductive gasket 100 may be easily maintained in flatness and may better perform the electromagnetic wave shielding due to the metal member.

When the metal member is attached to the metal layer 130 on the bottom surface of the electrically conductive gasket 100, the metal member may be a material that is capable of being soldered using solder cream.

In another embodiment, both ends of the polymer film 120 may be spaced apart from each other on the bottom surface of the electrically conductive gasket 100 to define a gap, and thus, a portion of the support layer 142 may be exposed to the outside through the gap 111.

In this structure, the support layer 142 may have electrical conductivity because the electrically conductive powder is disposed in the support layer 142 and may be exposed to the outside through the gap 111 and thus be electrically connected to the electrically conductive adhesive tape 150, which is in contact therewith, or the electrically conductive object.

As a result, the electromagnetic waves that are introduced or emitted through both ends of the electrically conductive gasket 100 in a longitudinal direction may be shielded to improve the electromagnetic wave shielding performance of the entire electrically conductive gasket 100.

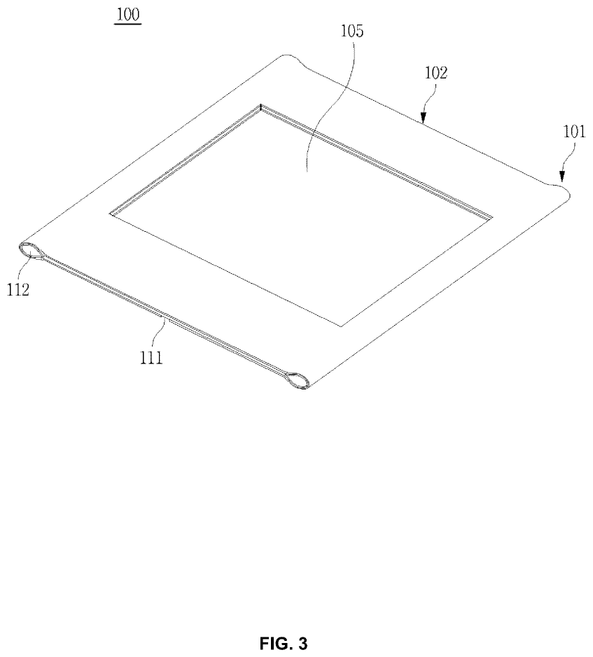

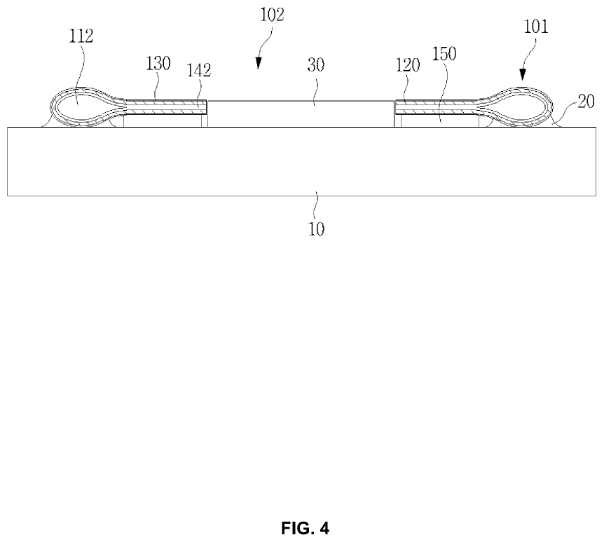

FIG. 3 is a view illustrating an electrically conductive gasket according to another embodiment of the present invention, and FIG. 4 is a view illustrating a state in which the electrically conductive gasket is mounted on a circuit board.

In this embodiment, at least one opening 105 passing through an electrically conductive film 110 in a thickness direction is defined in a support part 102, and a bending portion 101 is provided in a pair at both ends of the support part 102 in a width direction.

Preferably, the pair of bending portions 101 may be symmetrical to achieve balance with an object.

In this example, the opening 105 may be defined in the support part 102 in a rectangular shape corresponding to, for example, a semiconductor chip 30, but the shape of the opening 105 may not be limited thereto, and may be defined in shapes corresponding to electronic components or circuit boards having the various shapes.

In addition, heights of the plurality of semiconductor chips 30 or circuit boards 10 may be different from each other, and the plurality of semiconductor chips 30 may also be mounted on circuit boards different from each other.

Preferably, a maximum height of the bending portion 101 is greater than a maximum height of the semiconductor chip 30 accommodated in the opening 105 and mounted on the circuit board 10.

When the facing object presses the electrically conductive gasket 100 in the vertical direction, the powder contained in the support layer 142 and the support part 102 may serve to prevent the object from being in contact with a surface of the semiconductor chip 30, thereby allowing the support part 102 to mechanically protect the semiconductor chip 30 while shielding the electromagnetic waves.

In this case, the support layer 142 preferably contains the electrically conductive powder to provide electrical conductivity.

When the electrically conductive gasket 100 having this structure is interposed to be pressed by the facing electrically conductive object, the support layer 142 may have the electrical conductivity to more effectively shield the electromagnetic waves, which are introduced or emitted in the horizontal direction of the semiconductor chip 30 accommodated in the opening 105 that is not covered by the electrically conductive film 110.

As described below, when a height of the semiconductor chip 30 is higher than the maximum height of the bending portion 101 of the electrically conductive gasket 100, or if necessary, the electrically conductive gasket 100 may not be directly mounted on the circuit board, but may be mounted on a shield case or shield frame that is soldered to the circuit board to surround the semiconductor chip mounted on the circuit board so as to shield the electromagnetic waves.

In this case, the electrically conductive gasket 100 mounted on the shield case or shield frame is in elastic contact with the facing electrically conductive member that covers the shield case or shield frame.

As illustrated in FIG. 4, the electrically conductive gasket 100 of

the present invention is considered to be interposed to be pressed between the facing objects.

The electrically conductive gasket 100 may be mounted by soldering a portion of a bottom surface of the bending portion 101 to the circuit board 10 using a solder 20 or may be mounted on the circuit board 10 by allowing an adhesive tape 150 to adhere to a metal layer 130 on the bottom surface of the electrically conductive gasket 100 corresponding to the support part 102 except for the opening 105 and the bending portion 101. That is, the electrically conductive gasket 100 may be attached to the circuit board 10 or the electrically conductive object by the soldering or using the adhesive tape.

Preferably, the electrically conductive gasket 100 provides a space for vacuum pickup in the support part 102 so as to be surface-mounted by the vacuum pickup.

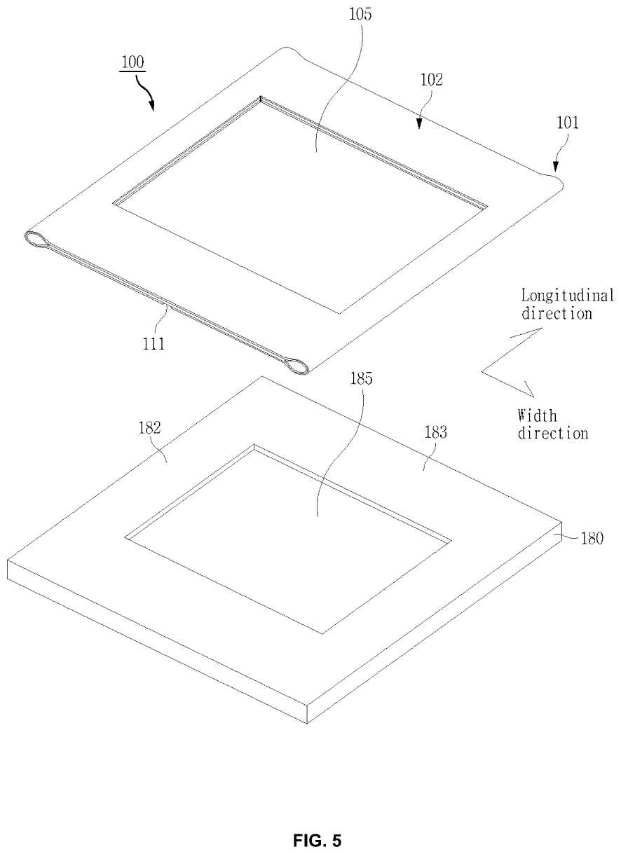

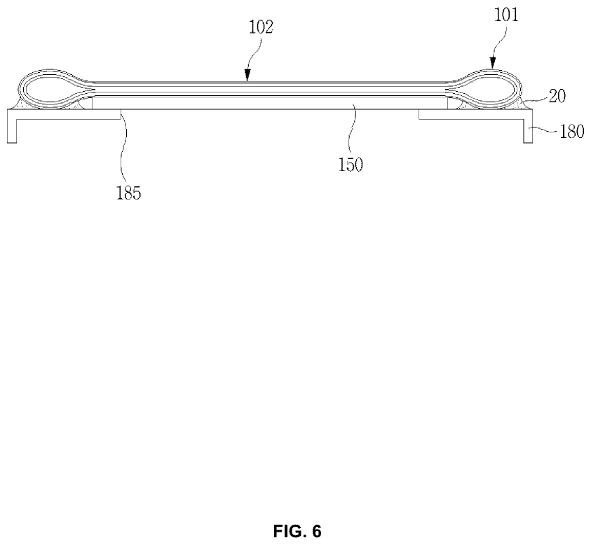

FIG. 5 is an exploded view illustrating an electromagnetic wave shielding device according to an embodiment of the present invention, and FIG. 6 is a cross-sectional view illustrating an integrated electromagnetic wave shielding device.

The electromagnetic wave shielding device is provided with a metal shield case 180 having an opening 185 in a top surface thereof and flanges 182 and 183 along an edge of the opening 185, and an electrically conductive gasket 100 attached to the flanges 182 and 183.

The electrically conductive gasket 100 has the same structure as the electrically conductive gasket 100 according to the embodiment of FIG. 3, and thus detailed descriptions thereof are omitted.

The electromagnetic wave shielding device may be vacuum-picked up at a portion of the electrically conductive gasket 100 so as to be surface-mounted on an object such as a circuit board, but may also be vacuum-picked up at the flanges 182 and 183 on which the electrically conductive gasket 100 is not provided.

Preferably, the electrically conductive gasket 100 may correspond to a soldering temperature, a metal shield case 180 may be mounted on the circuit board or the like by soldering, and a height of the metal shield case 180 may be higher than a maximum height of the electrically conductive gasket 100.

A size of the opening 185 of the metal shield case 180 may correspond to a size of the semiconductor chip mounted on the circuit board and may be smaller than or equal to the size of the opening 105 of the electrically conductive gasket 100. Each of the openings 185 and 105 may be provided in one or more pieces.

The electrically conductive gasket 100 is largely pressed with less force at a thin thickness and has elastic restoring force and thus is interposed to be pressed between the facing metal shield case 180 and cooling unit, thereby shielding electromagnetic waves or providing electrical connection.

The electrically conductive gasket 100 may be soldered to the object by solder cream or may be attached to the object by the adhesive tape 150 adhering to the electrically conductive gasket 100.

The electrically conductive gasket 100 may be mounted by soldering a portion of a bottom surface of the bending portion 101 to the flange 182 using a solder 20 and may be mounted on the flange 183 by allowing the adhesive tape 150 to adhere to a metal layer 130 on a bottom surface of the electrically conductive gasket 100 corresponding to a support part 102 except for the opening 105 and the bending portion 101.

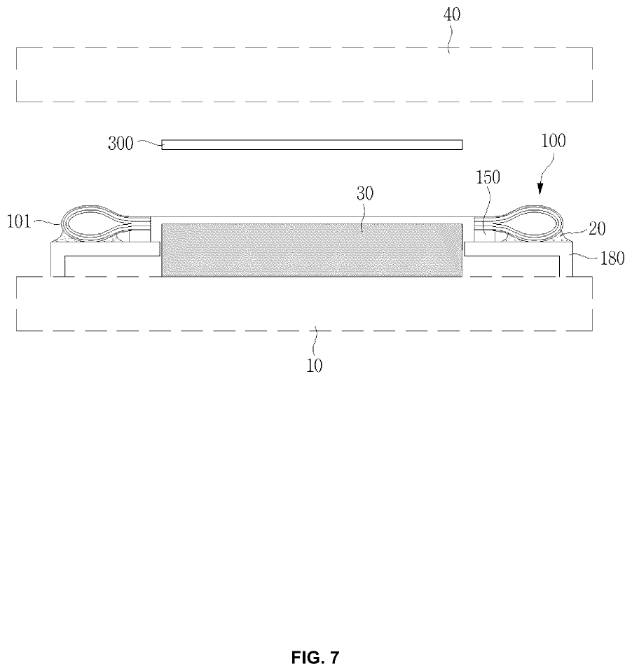

FIG. 7 is a view illustrating a state in which the electromagnetic wave shielding device is applied.

At least one or more semiconductor chips 30 is mounted on the circuit board 10, and an integrated electromagnetic wave shielding device is mounted on the circuit board 10 to surround the semiconductor chips 30.

Here, the semiconductor chip 30 includes not only a single semiconductor chip but also a semiconductor chip mounted on a sub-circuit board.

A height of a top surface of the semiconductor chip 30 is lower than a maximum height of the bending portion 101 of the electrically conductive gasket 100, and a thermoelectric member 300 having a thickness corresponding to a corresponding height difference is interposed between the semiconductor chip 30 and the cooling unit 40.

The thermoelectric member 300 may be in a gel or grease state, and after the electromagnetic wave shielding device is soldered to the circuit board 10, the thermoelectric member 300 may be disposed on the top surface of the semiconductor chip 30.

According to this structure, electromagnetic waves that are introduced into the semiconductor chip 30 or emitted from the semiconductor chip 30 may be shielded in all directions by the integrated electromagnetic wave shielding device to improve reliability of electromagnetic wave shielding and also to quickly transfer heat emitted from the semiconductor chip 30 to the cooling unit through the thin thermal conductive member.

Here, in the state in which the metal shield case 180 is mounted on the circuit board 10, the electrically conductive gasket 100 may be attached to the flange of the metal shield case 180 to provide the electromagnetic wave shielding device, or the electrically conductive gasket 100 may be attached to the flange of the metal shield case 180 to provide the integrated electromagnetic wave shielding device, and then, the integrated electromagnetic wave shielding device may be mounted on the circuit board 10.

Referring to FIG. 7, when the cooling unit 40 presses the electrically conductive gasket 100 in the vertical direction, the bending portion 101 is in contact with the cooling unit 40 first so as to be pressed, and then, the cooling unit 40 presses the support part 102.

Here, if powder is dispersed in the support layer 142, as described above, the powder serves as a spacer to prevent the cooling unit 40 from being in contact with a surface of the semiconductor chip 30 and pressing the semiconductor chip 30, thereby allowing the support part 102 to mechanically protect the semiconductor chip 30 while shielding the electromagnetic waves.

Particularly, when the powder contained in the support layer 142 is electrically conductive powder, the more amount of electromagnetic waves that are introduced from both ends, which are not covered by the polymer film 120, in a horizontal direction of the semiconductor chip 30 or are emitted from both the ends, may be shielded.

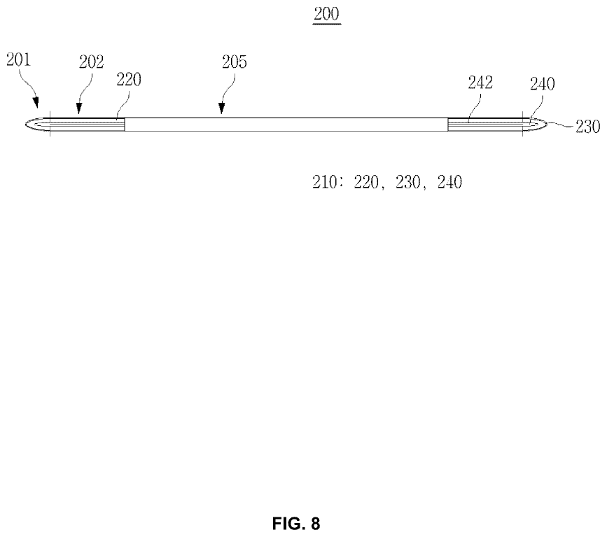

FIG. 8 is a view illustrating an electrically conductive gasket according to another embodiment of the present invention.

An electrically conductive film 210 is bent at both sides so that an adhesive layer 240 is disposed at an inner side to provide a bending portion 201. Unlike the foregoing embodiment, an inner space is not defined in the bending portion 201, and adhesive layers 240 therein adhere to each other to provide a support layer 242.

Thus, the adhesive layers 240 may adhere to each other inside both the bending portion 201 and the support part 202, which are provided by the electrically conductive film 210, to provide the support layer 242.

An opening 205 pass through the electrically conductive gasket 200 in the thickness direction is defined in the support part 202.

According to this structure, since the support part 202 is maintained at the same height up to a boundary of the bending portion 201, which is indicated by dotted lines in FIG. 8, a maximum height of the bending portion 201 is equal to a maximum height of the support part 202. In addition, the height of the bending portion 201 decreases as it approaches an end thereof, resulting in a cross-section having an elliptical shape.

Although the embodiments of the present invention have been described above, various changes and modifications which can be understood by a person skilled in the art may also be made. Such the changes and modifications can be considered to fall within the scope of the present invention. The scope of rights of the present invention should be determined by the claims set forth below.

What is claimed is:

1. An electrically conductive gasket, which is interposed between facing objects to shield electromagnetic waves or provide electrical connection the facing objects, the electrically conductive gasket comprising:
an electrically conductive member; and
an electrically conductive film provided as a curable adhesive layer having elasticity, which adheres to the electrically conductive member by curing,
wherein the electrically conductive film is bent in a curved shape at each of both sides of the electrically conductive gasket in a width direction so that the adhesive layer is disposed inside to provide a bending portion having one inner space extending in a longitudinal direction of the electrically conductive gasket,
the adhesive layers adhere to each other at a portion at which the electrically conductive films overlap to face each other except for the bending portion to provide a support layer, wherein a support part is provided by the portion, at which the electrically conductive films overlap each other, and the support layer,
a maximum height of the bending portion is higher than a maximum height of the support part, and
when each of the objects presses the gasket, the gasket is in contact with elastic contact with the object due to elastic restoring force of the bending portion.

2. The electrically conductive gasket of claim 1, wherein the electrically conductive member is a polymer film having one surface, on which a metal layer is disposed, and the other surface, to which the adhesive layer adheres, or an electrically conductive fiber to which the adhesive layer adheres, and
the metal layer is provided by plating or provided as metal foil.

3. The electrically conductive gasket of claim 1, wherein the support part is flat, and
both ends of the electrically conductive member are disposed on a bottom surface of the support part.

4. The electrically conductive gasket of claim 3, wherein a plurality of microvoids caused by air, which is smaller than the inner space, are provided in the support layer to more soften the support part.

5. The electrically conductive gasket of claim 1, wherein a cross-section of the electrically conductive gasket is symmetrical in the width direction.

6. The electrically conductive gasket of claim 1, wherein a cross-section of the bending portion has a circular or elliptical shape in which a height of an intermediate portion in a horizontal direction becomes a maximum height.

7. The electrically conductive gasket of claim 1, wherein an adhesive tape adheres to the electrically conductive member disposed on a bottom surface of the support part,
wherein the tape does not protrude beyond the lowermost portion of the bending portion so that the electrically conductive member disposed on the bottom surface of the support part is in direct contact with the object.

8. The electrically conductive gasket of claim 1, wherein one or more openings passing through the electrically conductive gasket in a thickness direction are defined in a portion of the support part.

9. The electrically conductive gasket of claim 8, wherein a maximum height of the gasket at the bending portion is greater than a maximum height of a semiconductor chip accommodated in each of the openings and mounted on a circuit board.

10. The electrically conductive gasket of claim 8, wherein electrically conductive powder is mixed into the support layer to shield electromagnetic waves, which are introduced into or emitted from the semiconductor chip accommodated in the opening in a direction, in which the bending portion is not provided through the support layer.

11. The electrically conductive gasket of claim 1, wherein the electrically conductive member comprises:
a polymer film having one surface on which a metal layer is disposed, or an electrically conductive fiber adheres; and
a flat reinforcing sheet having one surface, to which the other surface of the polymer film adheres, and the other surface, to which the adhesive layer adheres.

12. The electrically conductive gasket of claim 1, wherein the inner space surrounded by the electrically conductive film is defined in the bending portion because the adhesive layers do not adhere to each other, or
the adhesive layers adhere to each other on the bending portion so as to be connected to the support layer.

13. An electromagnetic wave shielding device, which surrounds a semiconductor chip mounted on a circuit board to shield electromagnetic waves, the electromagnetic wave shielding device comprising:
a metal shield case having an opening in a top surface thereof and provided with a flange along an edge of the opening; and
an electrically conductive gasket attached to a top surface of the flange,
wherein the electrically conductive gasket comprises the electrically conductive member, and an electrically conductive film provided as a curable adhesive layer having elasticity, which adheres to the electrically conductive member by curing,
the electrically conductive film is bent in a curved shape at each of both sides of the electrically conductive gasket in a width direction so that the adhesive layer is disposed inside to provide a bending portion having one inner space extending in a longitudinal direction of the electrically conductive gasket,
the adhesive layers adhere to each other at a portion at which the electrically conductive films overlap to face each other except for the bending portion to provide a support layer, wherein a support part is provided by the portion, at which the electrically conductive films overlap each other, and the support layer,
an opening passing through the electrically conductive gasket in a thickness direction is defined in the support part,
a maximum height of the bending portion is higher than a maximum height of the support part,
when each of the objects presses the gasket, the gasket is in contact with elastic contact with the object due to elastic restoring force of the bending portion, and
a surface of the semiconductor chip is exposed to the outside through the opening of the gasket and the opening of the shield case.

14. The electromagnetic wave shielding device of claim 13, wherein the opening of the metal shield gasket and the opening of the electrically conductive gasket correspond to each other so that surfaces of two or more semiconductor chips are exposed to the outside.

15. The electromagnetic wave shielding device of claim 13, wherein the electrically conductive gasket is mounted inside an edge of the metal shield case.

16. The electromagnetic wave shielding device of claim 13, wherein the electrically conductive gasket corresponds to a soldering temperature,
the metal shield case is suitable for soldering, and
the electromagnetic wave shielding device is surface-mounted by vacuum pickup at a portion of the electrically conductive gasket.

17. A mounting structure of the electromagnetic wave shielding device of claim 13,
wherein the support part of the electrically conductive gasket is attached to a bottom surface of a cooling unit by interposing an adhesive means therebetween, and
the bending portion of the electrically conductive gasket is in contact with the flange of a metal shield case mounted on the facing circuit board to provide the electromagnetic wave shielding device.

18. The mounting structure of claim 17, wherein the surface of the semiconductor chip and the bottom surface of the cooling unit are thermally coupled by interposing a thermoelectric member therebetween through the opening of the metal shield case and the opening of the electrically conductive gasket.
